(19) United States
(12) Patent Application Publication
(10) Pub. No.: US 2025/0126783 A1
(43) Pub. Date: Apr. 17, 2025

(54) VERTICAL FIELD EFFECT TRANSISTOR, AND MANUFACTURING METHOD THEREOF

(71) Applicant: KOREA NATIONAL UNIVERSITY OF TRANSPORTATION INDUSTRY-ACADEMIC COOPERATION FOUNDATION, Chungju-si (KR)

(72) Inventors: Myounggon Kang, Suwon-Si (KR); Seungjae Baik, Anseong-Si (KR); Geonwoong Kim, Yongin-Si (KR)

(73) Assignee: KOREA NATIONAL UNIVERSITY OF TRANSPORTATION INDUSTRY-ACADEMIC COOPERATION FOUNDATION, Chungju-si (KR)

(21) Appl. No.: 18/717,168

(22) PCT Filed: Dec. 7, 2022
(86) PCT No.: PCT/KR2022/019767

§ 371 Date: Dec. 23, 2024

(30) Foreign Application Priority Data
Dec. 9, 2021 (KR) 10-2021-0176041

(51) Int. Cl. H10B 41/70

(52) U.S. Cl. CPC H10B 41/70

(57) ABSTRACT

The disclosure relates to a vertical field effect transistor, and a manufacturing method thereof. The vertical field effect transistor according to an embodiment may include: a substrate; a source region, an insulating layer, and a drain region stacked vertically on the substrate; and a tunnel barrier, an active region, a gate barrier, and a gate region are stacked to surround a top surface of the substrate, and the source region, the insulating layer, and the drain region vertically stacked.

### TECHNICAL FIELD

The following description relates to a vertical field effect transistor, and manufacturing method thereof.

### BACKGROUND ART

As electronic devices become more miniaturized, high-performance and/or low-power, transistors are being developed and manufactured using silicon on insulator (SOI) structures due to their advantages in switching speed, current gain, high voltage endurance and/or power consumption. In addition, transistors are being developed and manufactured using vertical structures due to the advantages of density. For example, a double-gate field effect transistor (DGFET) with a vertical structure has been developed.

The double-gate field effect transistors with vertical structures require narrow channel widths to improve device characteristics. However, the process of mask patterning to make the channel narrow is very difficult, resulting in high channel width variability and high cost.

### DISCLOSURE

### Technical Problem

An aspect of the present invention is to provide a vertical field effect transistor with an improved structure capable of reducing a difficulty of a manufacturing process, and a method of manufacturing the same.

Another aspect of the present invention is to provide a vertical field effect transistor with an improved structure capable of increasing device density and a method of manufacturing the same.

The problems that the present invention is intended to solve are not limited to those mentioned above, and other problems not mentioned will be apparent to those skilled in the art from the following description.

### Solution to Problem

In order to achieve this purpose, in one general aspect, a vertical field effect transistor includes: a substrate; a source region, an insulating layer, and a drain region vertically stacked on the substrate; and a tunnel barrier, an active region, a gate barrier, and a gate region stacked to surround the source region; the insulating layer; and the drain region vertically stacked on the substrate.

In another general aspect, a vertical field effect transistor includes: a substrate; a source region and an insulating layer vertically stacked on the substrate; a tunnel barrier formed to surround the source region and the insulating layer vertically stacked on the substrate; a first active region formed to be in contact with a horizontal plane of the tunnel barrier and a portion of the first vertical plane of the tunnel barrier; a second active region formed to be in contact with a horizontal plane of the tunnel barrier and a portion of the second vertical plane of the tunnel barrier; a first drain region stacked vertically with the first active region and formed to be in contact with another portion of the first vertical plane of the tunnel barrier; a second drain region stacked vertically with the second active region and formed to be in contact with another portion of the second vertical plane of the tunnel barrier; a gate barrier formed to surround the first active region, the first drain region, top surface of the tunnel barrier, the second drain region, and the second active region; and a gate region formed to surround the gate barrier.

In another general aspect, a method of manufacturing a vertical field effect transistor includes: stacking vertically a source region, an insulating film, and a drain region to form on a substrate; forming a hard mask layer on the drain region, and patterning; removing a portion of the stacked source region, insulating layer, and drain region; forming a tunnel barrier to surround a top surface of the substrate and the unremoved source region, insulating layer, and drain region; forming an active region to surround the tunnel barrier; forming a gate barrier to surround the active region; forming a gate region to surround the gate barrier; and forming metal electrodes in connection with the gate region, the source region, and the drain region, respectively.

### Effects of Invention

According to the present invention may allow a field effect transistor with a vertical structure to control the channel width through a deposition process rather than a mask patterning process, thereby reducing manufacturing complexity.

Furthermore, the present invention may increase the device density relative to area by controlling only the portion corresponding to the drain of the transistor to operate as individual transistors.

### BRIEF DESCRIPTION OF DRAWINGS

FIG. 1 illustrates a diagram of a structure of a field effect transistor with a vertical structure according to a first embodiment of the present invention.

FIG. 2 illustrates a diagram of a structure of a field effect transistor with a vertical structure according to a second embodiment of the present invention.

FIG. 3A illustrates a diagram of the structure of a floating gate field effect transistor using the field effect transistors with a vertical structure according to an embodiment of the present invention.

FIG. 3B illustrates a diagram of the equivalent circuit of FIG. 3A.

FIG. 4 illustrates a flowchart to illustrate a method for manufacturing a field effect transistor with a vertical structure according to an embodiment of the present invention.

FIGS. 5A to 5H illustrate drawings of a manufacturing process of a field effect transistor with a vertical structure according to an embodiment of the present invention.

### BEST MODE FOR IMPLEMENTATION OF THE INVENTION

Hereinafter, preferred embodiments of the present invention will be described in detail with reference to the accompanying drawings. Advantages and features of the present invention and a method of achieving them will become apparent with reference to the embodiments described below in detail with the accompanying drawings. However, the present invention is not limited to the embodiments disclosed below, but will be implemented in various forms, and only the present embodiments are provided to ensure that the disclosure of the present invention is complete, to fully inform those of ordinary skill in the art to which the present invention belongs, and the present invention is only defined by the scope of the claims. Hereinafter, the same reference numerals refer to the same elements.

Although first, second, etc. are used to describe various devices, components, and/or sections, these devices, components, and/or sections are not limited by these terms. These terms are used only to distinguish one device, component, or section from other devices, components, or sections. Therefore, it goes without saying that the first element, the first element, the first element, or the first section mentioned below may be a second element, a second element, or a second section within the technical idea of the present invention.

The terms used in the present invention are used only to describe a specific embodiment and are not intended to limit the present invention. Singular expressions include plural expressions unless the context clearly indicates otherwise. In the present application, the term “comprise” or “made of” is intended to specify that there is a feature, number, step, operation, component, part, or combination thereof described in the specification, and it should be understood not to preclude the presence or additional possibility of one or more other features or numbers, steps, operations, components, parts, or combinations thereof.

Unless otherwise defined, all terms used in this specification, including technical and scientific terms, are intended to have the meaning commonly understood by one having ordinary knowledge in the technical field to which the invention belongs. In addition, terms defined in commonly used dictionaries are not to be construed as anomalous or excessive unless expressly and specifically defined.

In the following, the invention will be described in more detail with reference to the accompanying drawings.

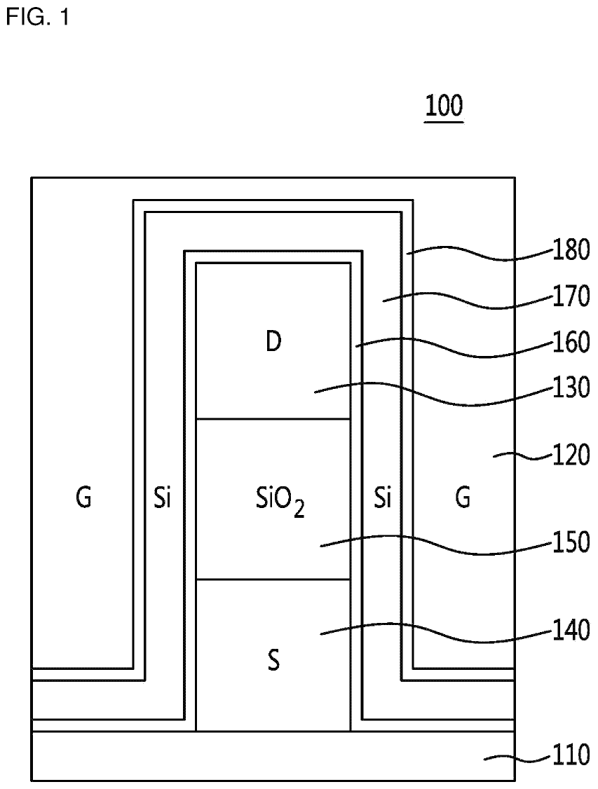

FIG. 1 illustrates a diagram of a structure of a field effect transistor with a vertical structure according to a first embodiment of the present invention.

Referring to FIG. 1, a vertical field effect transistor (VFET) 100 may include a substrate 110, a gate region 120, a drain region 130, a source region 140, an insulating layer 150, a tunnel barrier 160, an active region 170, and a gate barrier 180.

The vertical field effect transistor 100 may have a vertical structure in which the drain region 130 and the source region 140 are located on the upper and lower sides with respect to the insulating layer 150, rather than a planar structure in which the drain region 130 and the source region 140 are positioned horizontally on the left and right (or the front and rear) sides, respectively, with respect to the insulating layer 150. For example, in the vertical field effect transistor 100, the drain region 130 may be disposed (or formed) above the insulating layer 150, and the source region 140 may be positioned (or formed) below the insulating layer 150, as shown in

FIG. 1. Alternatively, in the vertical field effect transistor 100, the source region 140 may be positioned on the insulating layer 150, and the drain region 130 may be positioned below the insulating layer 150.

In addition, the vertical field effect transistor 100 may have the active region 170 on the left and right sides of the insulating layer 150. Additionally, the active region 170 may be disposed on the top surface of the substrate 110 and the top surface of the drain region 130. That is, the active region 170 may be formed to surround the source region 140, the insulating layer 150, and the drain region 130 vertically disposed on the substrate 110. Similarly, the tunnel barrier 160, the gate barrier 180, and the gate region 120 may be formed to surround the source region 140, the insulating layer 150, and the drain region 130. The tunnel barrier 160, the active region 170, the gate barrier 180, and the gate region 120 may be sequentially formed (stacked) to surround the source region 140, the insulating layer 150, and the drain region 130.

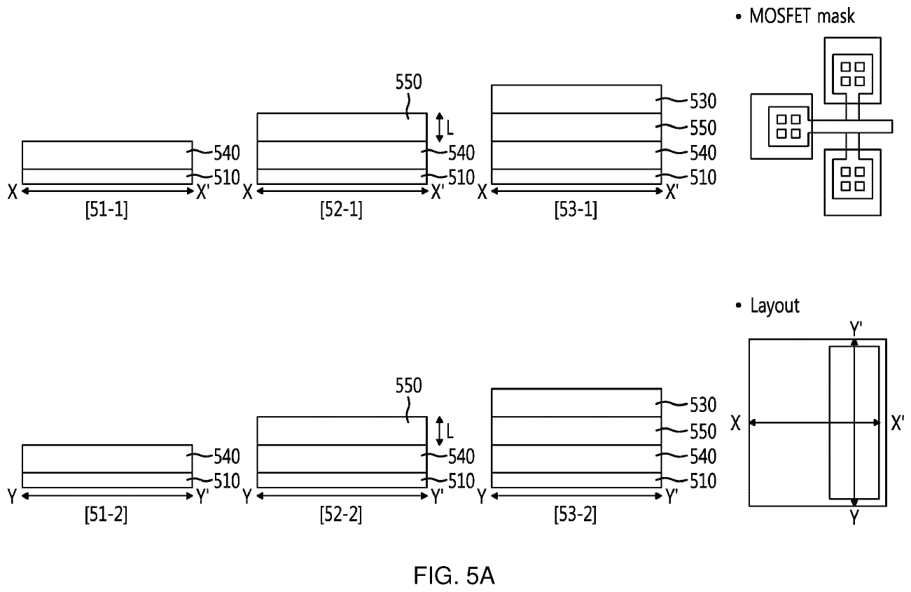

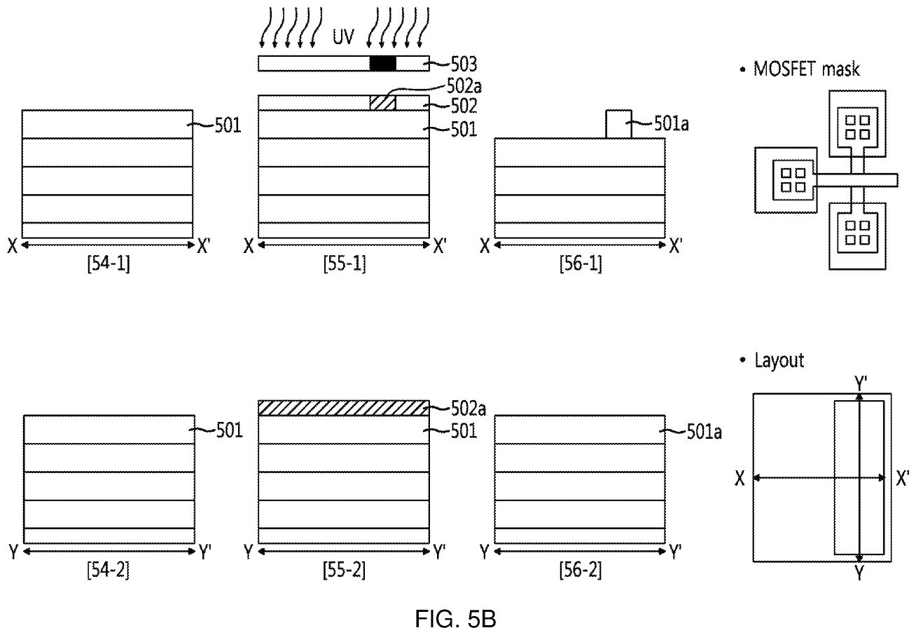

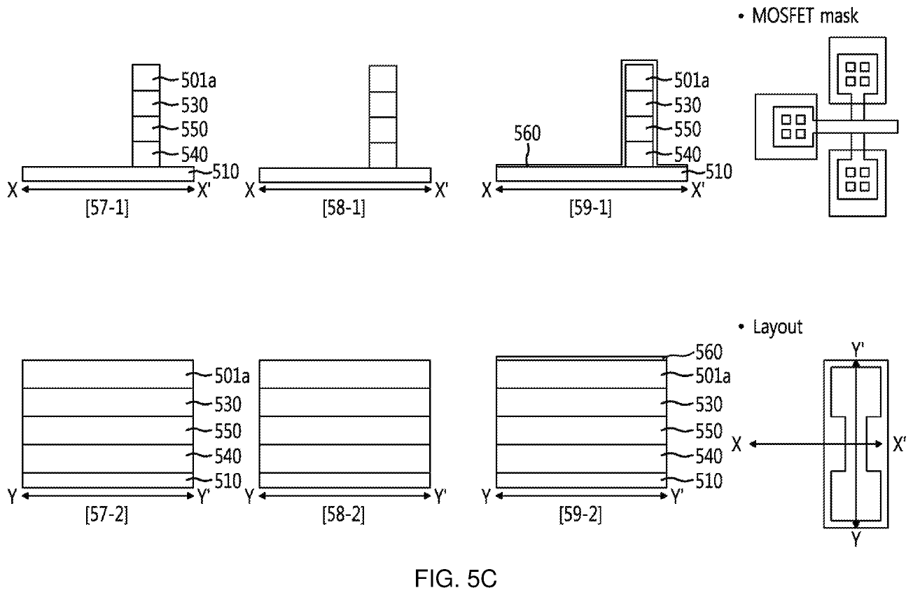

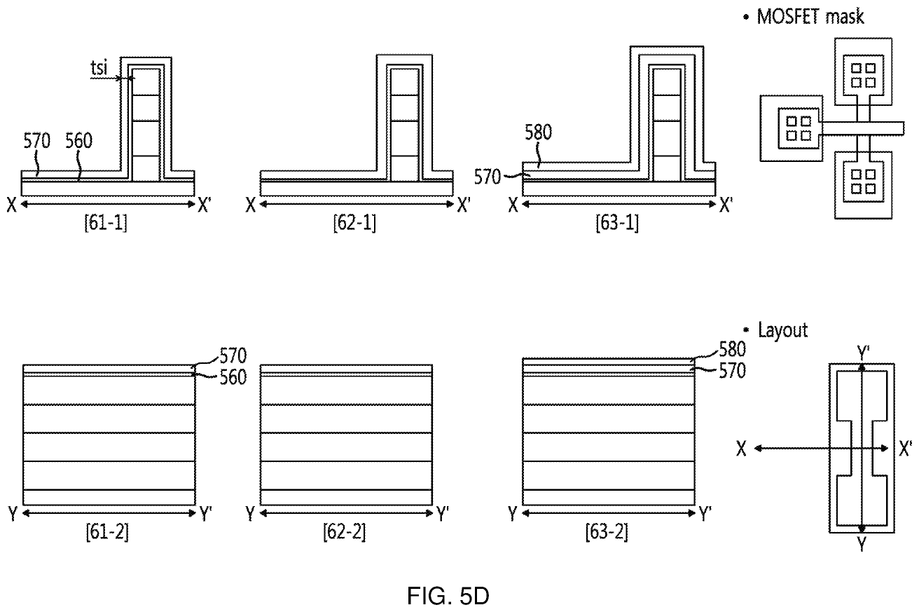

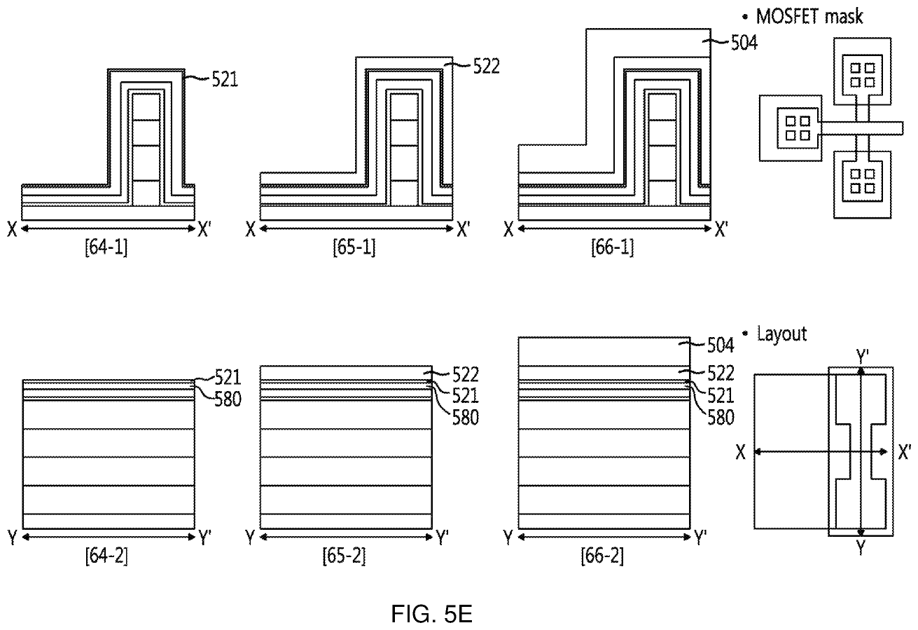

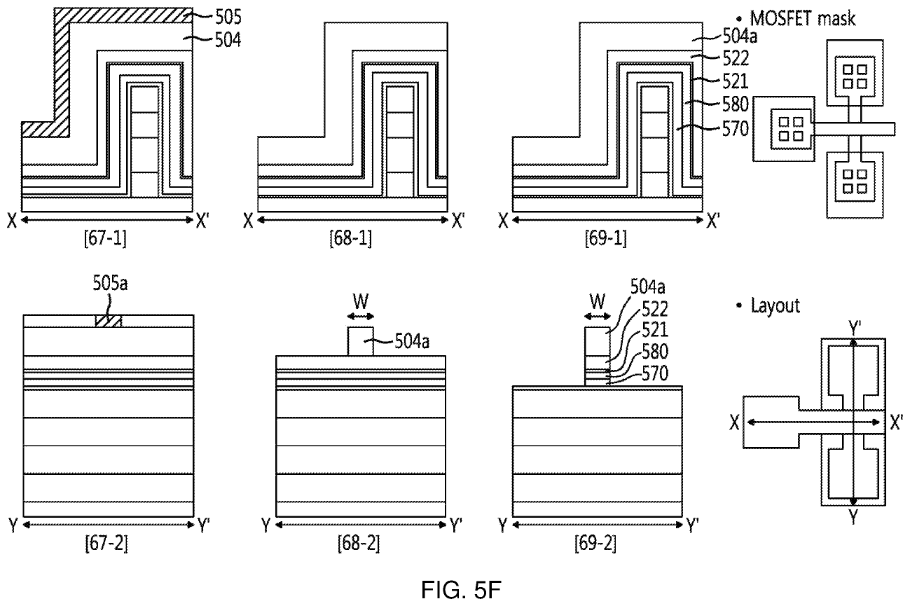

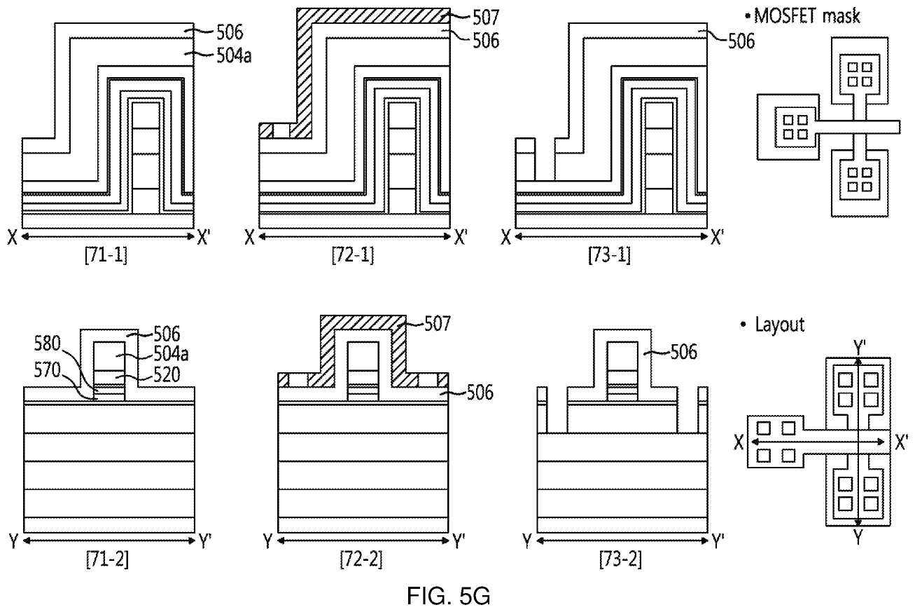

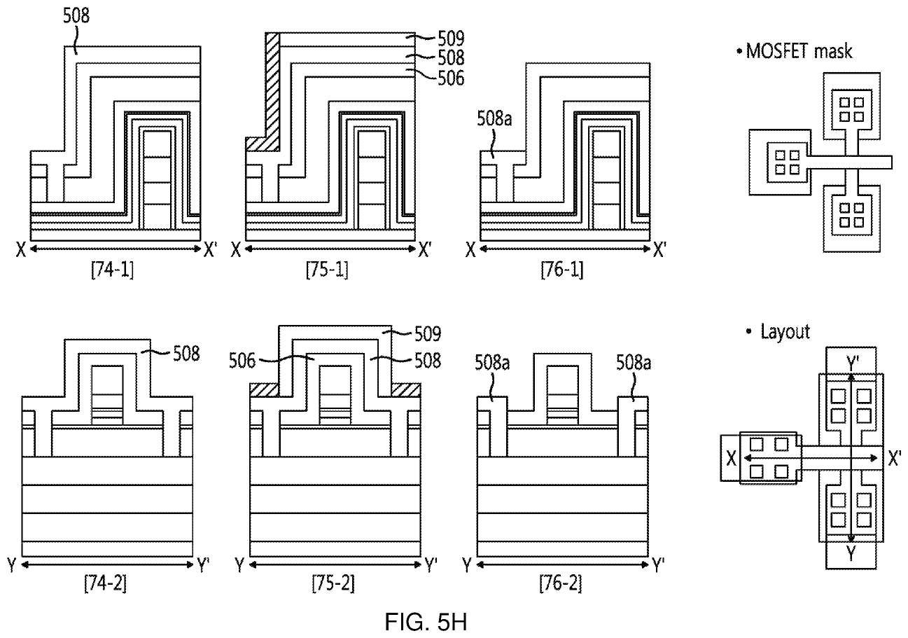

As shown in FIG. 1, the vertical field effect transistor 100 may have a staggered structure in which the gate region 120, the drain region 130, and the source region 140 are positioned opposite to each other with respect to the active region 170. In addition, as shown in FIG. 1, the vertical field effect transistor 100 may be a double-gate FET (DGFET) having two gate regions. This is merely an example, and the gate region 120 of the vertical field effect transistor 100 may have various known structures. For example, the vertical field effect transistor 100 may have one gate region or three gate regions. In addition, an insulator (a hard mask of 501 a of FIG. 5C, described later) may be positioned between the drain region 130 and the tunnel barrier 160.

The substrate 110 may be a silicon wafer. The gate region 120 may be formed of one of polysilicon (poly-Si), tungsten (W), tantalum (Ta), titanium nitrogen (TIN), tantalum nitrogen (TaN), or tungsten nitrogen (WN).

The drain region 130 and the source region 140 may be formed of polysilicon (poly-Si). The active region 170 may be the region where electrons move, and may be formed of a semiconductor material. For example, the active region 170 may be formed of one of silicon (Si), silicon germanium (SiGe), germanium (Ge), gallium arsenide (GaAs), indium gallium arsenide (InGaAs), or indium phosphide (InP). The tunnel barrier 160 and the gate barrier 180 may be formed of one of silicon oxide (SiO₂), hafnium oxide (HfO₂), and alumina (Al₂O₃). The insulating layer 150 may be formed of silicon oxide (SiO₂).

In general, the performance of the transistors may be determined by a critical dimension. For example, transistors with a planar structure may have their performance determined by the thickness of the active region, which is a critical dimension, while vertical field effect transistors with a structure in which the source region, the active region (or channel region), and the drain region are vertically stacked (hereinafter referred to as “conventional vertical field effect transistors”) may have their performance determined by the width of the active region (size in the horizontal direction), which is a critical dimension. In conventional vertical field effect transistors, the active region is formed between the source region and the drain region, such that the active region must be formed by a patterning process. In other words, in conventional vertical field effect transistors, the width of the active region is determined by a patterning process that is relatively difficult, expensive, and volatile. In contrast, the vertical field effect transistor 100 according to the present invention has a structure in which the active region 170 is in contact with (or surrounds) both sides of the vertically stacked source region 140, the insulating layer 150, and the drain region 130, and the top surface of the drain region 130, thereby allowing the active region 170 to be formed by a deposition process with relatively low process difficulty compared to the patterning process. As a result, the vertical field effect transistor 100 according to the present invention is easy to manufacture, may have reduced manufacturing costs, and has low variability. Meanwhile, a detailed description of the manufacturing process will be described hereinafter with reference to FIGS. 5A to 5H.

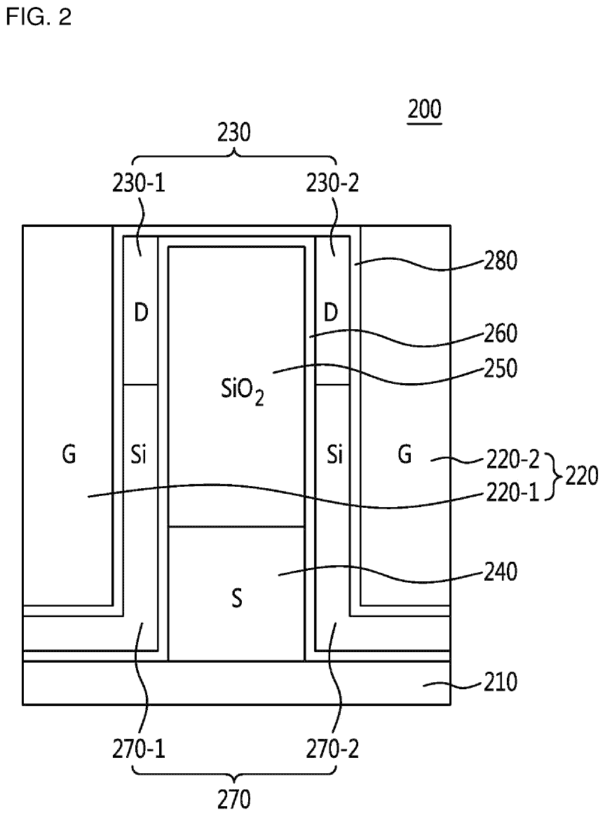

FIG. 2 illustrates a diagram of a structure of a field effect transistor with a vertical structure according to a second embodiment of the present invention.

Referring to FIG. 2, a field effect transistor 200 with a vertical structure according to the second embodiment of the present invention is similar to the vertical field effect transistor 100 of FIG. 1. However, the drain region 230 may be divided into two drain regions 230-1 and 230-2, and the gate region 220 may be divided into two gate regions 220-1 and 220-2 to operate as two transistors.

The vertical field effect transistor 200 according to the second embodiment may include a substrate 210, a gate region 220, a drain region 230, a source region 240, an insulating layer 250, a tunnel barrier 260, an active region 270, and a gate barrier 280. The gate region 220 may include a first gate region 220-1 and a second gate region 220-2. The drain region 230 may include a first drain region 230-1 and a second drain region 230-2. The active region 270 may include a first active region 270-1 and a second active region 270-2.

The source region 240 and the insulating layer 250 of the vertical field effect transistor 200 including the above-described configuration may be vertically stacked on the substrate 210, and the tunnel barrier 260 may be formed to surround the vertically stacked source region 240 and the insulating layer 250. Specifically, the tunnel barrier 260 may be stacked on (or in contact with) the top surface of the substrate 210, both sides of the vertically stacked source region 240 and insulating layer 250, and the top surface of the insulating layer 250.

In addition, the first active region 270-1 may be formed on one side (for example, left side) of the tunnel barrier 260 and may be stacked on a section of the tunnel barrier 260. The second active region 270-2 may be formed on another side (for example, right side) of the tunnel barrier 260 and may be stacked on another section of the tunnel barrier 260.

In addition, the first drain region 230-1 may be stacked in a perpendicular direction to the first active region 270-1 and may be in contact with the tunnel barrier 260. The second drain region 230-2 may be stacked in a perpendicular direction to the second active region 270-2 and may be in contact with the tunnel barrier 260.

In addition, the gate barrier 280 may be formed to surround the first active region 270-1, the first drain region 230-1, the top surface of the tunnel barrier 260, the second drain region 230-2, and the second active region 270-2, and the gate region 220 may be formed to surround the gate barrier 280.

The vertical field effect transistor 200 according to the second embodiment of the present invention with the above-described structure, compared to the vertical field effect transistor 100 of FIG. 1, may provide the effect of being able to form two transistors in the same area, thereby increasing the device density.

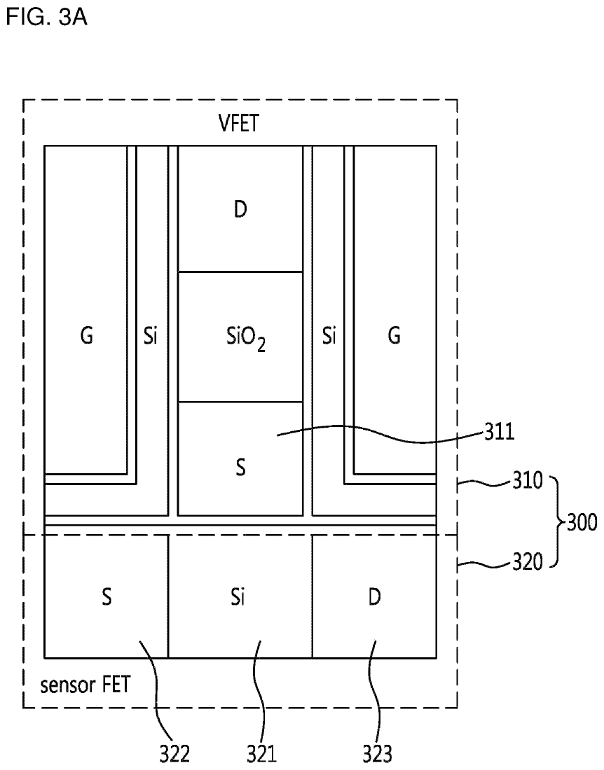

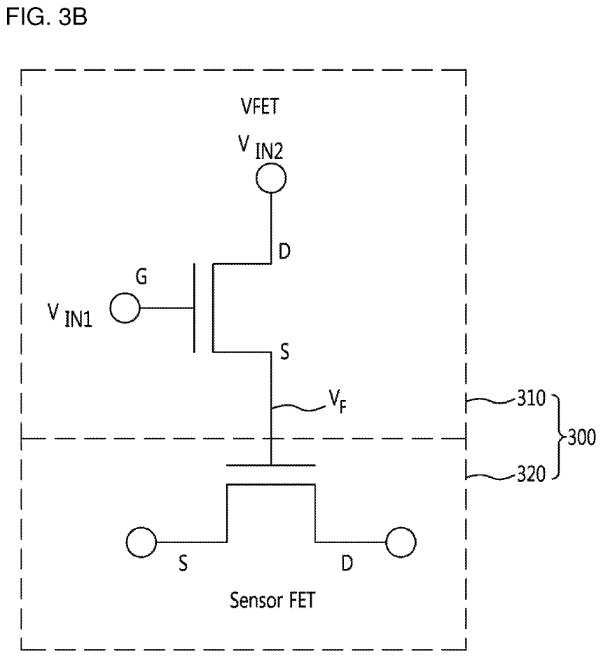

FIG. 3A illustrates a diagram of the structure of a floating gate field effect transistor using the field effect transistors with a vertical structure according to an embodiment of the present invention. FIG. 3B illustrates a diagram of the equivalent circuit of FIG. 3A.

Referring to FIGS. 3A and 3B, a vertical field effect transistor 310 (i.e., the vertical field effect transistor 100) and a sensor field effect transistor 320 may be combined to form a floating gate field effect transistor (floating FET, FGFET) 300. For example, the floating gate field effect transistor may be formed with an active region 321 of the sensor field effect transistor positioned below a source region 311 of the vertical field effect transistor 310; a source region 322 positioned on the left side of the active region 321; and a drain region 323 positioned on the right side of the active region 321. Thus, the floating gate field effect transistor 300 may be manufactured in a relatively simpler manner by adding the sensor field effect transistor 320 below the vertical field effect transistor 310. Furthermore, using only the floating gate field effect transistor 300, which has a simple structure, allows for the design of an integrated circuit. This can improve the area efficiency in manufacturing the integrated circuit, which can be advantageous for the integration process.

In the floating gate field effect transistor 300, the output of the forward voltage V_{F} may be determined according to the operation of the vertical field effect transistor 310 (in other words, whether V_{IN2} is output or not may be determined according to the V_{IN1}), and the operation of the sensor field effect transistor 320 may be determined by the forward voltage V_{F} (in other words, the forward voltage V_{F} determines the on/off state of the path (channel) between the drain D and source S of the sensor field effect transistor 320 may be determined by the forward voltage V_{F}. That is, the source region 311 of the vertical field effect transistor 310 can be utilized as the gate region of the sensor field effect transistor 320 without separately forming the gate region of the sensor field effect transistor 320. Additionally, the doping type of the vertical field effect transistor 310 and the sensor field effect transistor 320 may be changed according to the logic circuit.

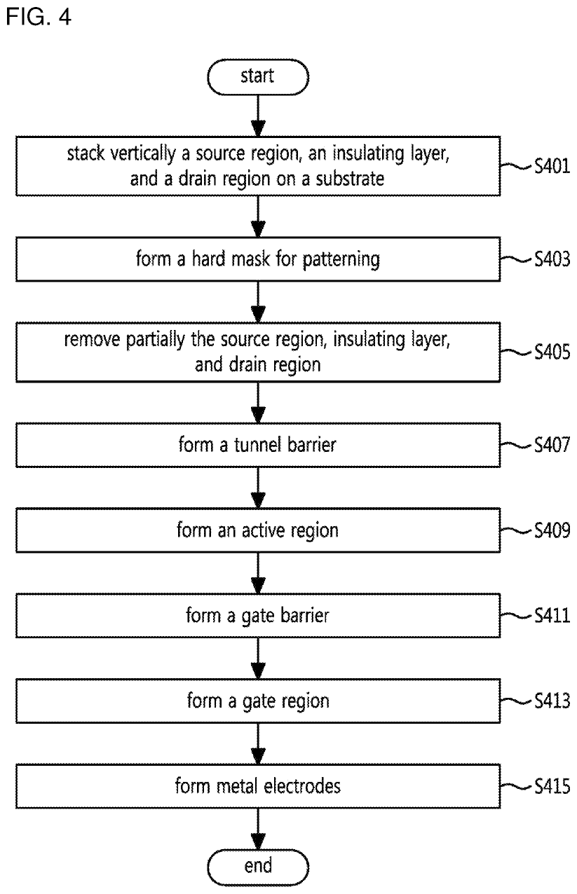

FIG. 4 illustrates a flowchart to illustrate a method for manufacturing a field effect transistor with a vertical structure according to an embodiment of the present invention. FIGS. 5A to 5H illustrate drawings of a manufacturing process of a field effect transistor with a vertical structure according to an embodiment of the present invention.

Prior to the detailed description, FIGS. 5A to 5H illustrate cross-sectional views in the X-axis direction at the top and cross-sectional views in the Y-axis direction at the bottom.

Referring to FIGS. 4 to 5H, a method of manufacturing a field effect transistor with a vertical structure according to an embodiment of the present disclosure (hereinafter referred to as “manufacturing method”) may include a step of vertically stacking a source region, an insulating layer, and a drain region on a substrate (S401). For example, a source region (for example, type I (N+) silicon) 540 is stacked (i.e., deposition) on a substrate (e.g., silicon wafer) 510, as indicated by numeric forms 51-1 and 51-2 in FIG. 5A; an insulating layer (e.g., silicon oxide (SiO₂)) 550 is stacked on the source region 540, as indicated by numeric forms 52-1 and 52-2; and a drain region (e.g., type I (N+) silicon (Si)) 530 may be stacked (i.e., deposited) on the insulating layer 550, as indicated by numeric forms 53-1 and 53-2.

The manufacturing method according to an embodiment may include a step of forming and patterning a hard mask layer (S403). For example, a hard mask 501 may be stacked (i.e., deposition) on a drain region 530, as indicated by numeric forms 54-1 and 54-2 in FIG. 5B; a photoresist (PR) 502 is applied to the top surface of the hard mask 50, the applied photoresist 502 is removed, with the exception of a portion 502a, using the photomask 503 and infrared rays, as indicated by numeric forms 55-1 and 55-2; and the hard mask 501 is removed, with the exception of a portion 501a, through the etching process, and then the portion 502a of the photoresist that was not removed may be removed through the PR strip process to perform patterning, as indicated by numeric forms 56-1 and 56-2.

The manufacturing method according to an embodiment may include a step of removing partially the stacked source region, insulating layer, and drain region (S405). For example, an etching process may be used to remove the source region 540, the insulating layer 550, and the drain region 530, with the exception of the portion (below the hard mask's the portion 501a), as indicated by numeric forms 57-1 and 57-2 in FIG. 5C. The removal step may then include a cleaning process, as indicated by numeric forms 58-1 and 58-2 in FIG. 5C.

The manufacturing method according to an embodiment may include a step of forming a tunnel barrier (also referred to as “tunnel oxide”) (S407). The tunnel barrier may be formed to surround the top surface of the substrate and the unremoved source region, the insulating layer, and the drain region. For example, a deposition process may be used to form a tunnel barrier 560, as shown by identification symbols 59-1 and 59-2 in FIG. 5C. Referring to cross-sectional view 59-1 in the x-axis direction, the tunnel barrier 560 may surround the top surface of the substrate 510, and the unremoved source region 540, the insulating layer 550, the drain region 530, and the mask region 501a. The deposition process may utilize an atomic layer deposition (ALD) method, a chemical vapor deposition (CVD) method, etc. Alternatively, the tunnel barrier 560 may be formed via an oxidation process.

The manufacturing method according to an embodiment may include a step of forming an active region (also referred to as “channel region”) (S409). For example, an active region 570 may be formed to be stacked (contacted) on the tunnel barrier 560, as indicated by numeric forms 61-1 and 61-2 in FIG. 5D. Referring to cross-sectional view 61-1 in the x-axis direction, the active region 570 may be shaped to surround the top surface of the substrate 510 and the unremoved source region 540, the insulating layer 550, the drain region 530, and the mask region 501a. The active region 570 may be formed through a deposition process. As the active region 570 is formed through the deposition process, the thickness of the active region (tₛᵢ), which is a critical dimension of the vertical field effect transistor, can be easily controlled and variability can be reduced. The step of forming the active region may comprise a cleaning process, as indicated by numeric forms 62-1 and 62-2. The cleaning process may be performed in one of a variety of ways known in the art.

The manufacturing method according to an embodiment may include a step of forming a gate barrier (S411). For example, a gate barrier (also referred to as “gate oxide film”) 580 may be formed to be stacked (contacted) on the active region 570, as indicated by numeric forms 63-1 and 63-2 in FIG. 5D. Referring to cross-sectional view 63-1 in the x-axis direction, the gate barrier 580 may be shaped to surround the top surface of the substrate 510, and the unremoved source region 540, the insulating layer 550, the drain region 530, and the mask region 501a. The gate barrier 580 may be formed through the deposition process (e.g., atomic layer deposition (ALD) method).

The manufacturing method according to an embodiment may include a step of forming a gate region (S413). For example, stacking a first material (e.g., titanium nitrogen (TIN)) 521 on a gate barrier 580, as indicated by numeric forms 64-1 and 64-2 in FIG. 5E; stacking a second material (e.g., type I polysilicon (N+ poly-Si)) 522 on the first material 521; and stacking a hard mask 504 on the second material 522, as indicated by numeric forms 66-1 and 66-2 in FIG. 5E. In addition, a photoresist (PR) 505 may be applied to the top surface of the hard mask 504, and a photomask (not shown) and infrared light may be used to remove the applied photoresist 505, with the exception of a portion 505a, as indicated by numeric forms 67-1 and 67-2 in FIG. 5F; the hard mask 504 is removed, with the exception of a portion 504a, through an etching process, and then the remaining portion 504a of the photoresist is removed through a PR Strip process, as indicated by numeric forms 68-1 and 68-2; and the etching process may remove the the active region 570, the gate barrier 580, the first material 521, and the second material 522 (located below the portion 504a of the hard mask) leaving a portion, to form the gate region 520, as indicated by numeric forms 69-1 and 69-2. Here, the first material 521 may be stacked by chemical vapor deposition (CVD), and the remainder of the active region 570, gate barrier 580, first material 521, and second material 522 may be removed by dry etching.

The manufacturing method according to an embodiment may include a step of forming metal electrodes (S415). For example, metal electrodes connected with drain regions may be formed through the process shown in FIGS. 5G and 5H. Specifically, referring to a top view 71-2 in the y-axis direction, an inter layer dielectric (ILD) 506 (e.g., SiO₂) is stacked to surround the active region 570, the gate barrier 580, gate region 520, and hard mask 504, as indicated by numeric forms 71-1 and 71-2 in FIG. 5G; a photoresist 507 is applied on the ILD 506, and a photomask (not shown) and infrared light is used to remove the applied photoresist 509 with the exception of a portion thereof, as indicated by numeric forms 72-1 and 72-2; and an etching process may be performed to remove partially the ILD 506 and hard mask 507, and then a PR Strip process (a process to remove the remaining parts not removed by infrared light) may be performed, as indicated by numeric forms 73-1 and 73-2. In addition, a metal region 508 may be formed on the ILD 506, as indicated by numeric forms 74-1 and 74-2 in FIG. 5H; a photoresist 509 may be applied on the metal region 508, and a photomask (not shown) and infrared light may be used to remove the majority of the applied photoresist 509, as indicated by numeric forms 75-1 and 75-2; and an etching process may be performed to remove the metal region 508, with the exception of a portion 508a, and then a PR Strip process may be performed (a process to remove the remainder that was not removed by infrared light), as indicated by numeric forms 76-1 and 76-2.

Although not shown, the manufacturing method may further include the step of forming a metal terminal that is connected to the gate region and the source region in a similar manner.

The vertical field effect transistor according to the present invention may be manufactured using a commonly used MOSFET mask. As a result, no additional manufacturing facility is required, and the manufacturing process can be simplified.

While the above has been described with reference to the illustrated embodiments of the invention, they are exemplary only, and it will be apparent to one having ordinary skill in the art to which the invention belongs that various modifications, changes, and equivalents are possible without departing from the spirit and scope of the invention. The true scope of technical protection of the invention should therefore be determined by the technical ideas of the appended claims.

What is claimed is:

1. A vertical field effect transistor, comprising:
a substrate;
a source region, an insulating layer, and a drain region vertically stacked on the substrate; and
a tunnel barrier, an active region, a gate barrier, and a gate region stacked to surround the source region; the insulating layer; and the drain region vertically stacked on the substrate.

2. The vertical field effect transistor of claim 1,
wherein a thickness of the active region is controlled through a deposition process.

3. The vertical field effect transistor of claim 1,
wherein the tunnel barrier and the gate barrier are formed of one of silicon oxide (SiO₂), hafnium oxide (HfO₂), or alumina (Al₂O₃).

4. The vertical field effect transistor of claim 1,
wherein the gate region is formed of one of polysilicon (poly-Si), tungsten (W), tantalum (Ta), titanium nitrogen (TIN), tantalum nitrogen (TaN), or tungsten nitrogen (WN),
wherein the drain region and the source region are formed of polysilicon (poly-Si), and
wherein the active region is formed of one of silicon (Si), silicon-germanium (SiGe), germanium (Ge), gallium arsenide (GaAs), indium gallium arsenide (InGaAs), or indium phosphide (InP).

5. A vertical field effect transistor, comprising:
a substrate;
a source region and an insulating layer vertically stacked on the substrate;
a tunnel barrier formed to surround the source region and the insulating layer vertically stacked on the substrate;
a first active region formed to be in contact with a horizontal plane of the tunnel barrier and a portion of the first vertical plane of the tunnel barrier;
a second active region formed to be in contact with a horizontal plane of the tunnel barrier and a portion of the second vertical plane of the tunnel barrier;
a first drain region stacked vertically with the first active region and formed to be in contact with another portion of the first vertical plane of the tunnel barrier;
a second drain region stacked vertically with the second active region and formed to be in contact with another portion of the second vertical plane of the tunnel barrier;
a gate barrier formed to surround the first active region, the first drain region, top surface of the tunnel barrier, the second drain region, and the second active region; and
a gate region formed to surround the gate barrier.

6. The vertical field effect transistor of claim 1,
wherein the first active region and the second active region are formed through a deposition process.

7. A method of manufacturing a vertical field effect transistor, comprising:
stacking vertically a source region, an insulating film, and a drain region to form on a substrate;
forming a hard mask layer on the drain region, and patterning;
removing a portion of the stacked source region, insulating layer, and drain region;
forming a tunnel barrier to surround a top surface of the substrate and the unremoved source region, insulating layer, and drain region;
forming an active region to surround the tunnel barrier;
forming a gate barrier to surround the active region;
forming a gate region to surround the gate barrier; and
forming metal electrodes in connection with the gate region, the source region, and the drain region, respectively.

8. The method of claim 7,
wherein the formation of the active region comprises forming the active region to a predetermined thickness by a deposition process.

9. The method of claim 7,
wherein the tunnel barrier and the gate barrier are formed of one of silicon oxide (SiO₂), hafnium oxide (HfO₂), and alumina (Al₂O₃).

10. The method of claim 7,
wherein the gate region is formed of one of polysilicon (poly-Si), tungsten (W), tantalum (Ta), titanium nitrogen (TIN), tantalum nitrogen (TaN), or tungsten nitrogen (WN),
wherein the drain region and the source region are formed of polysilicon (poly-Si), and
wherein the active region is formed of one of silicon (Si), silicon-germanium (SiGe), germanium (Ge), gallium arsenide (GaAs), indium gallium arsenide (InGaAs), or indium phosphide (InP).
